(19) United States
(12) Patent Application Publication
(10) Pub. No.: US 2014/0301026 A1
(43) Pub. Date: Oct. 9, 2014

(54) FLEXIBLE ELECTRONIC DEVICE

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: YU-TAI LIU, New Taipei (TW); CHUAN-WEI ZHANG, Shenzhen (CN); CHIN-CHUNG FU, New Taipei (TW)

(73) Assignees: HONG FU JIN PRECISION INDUSTRY (ShenZhen) CO., LTD, Shenzhen (CN); HON HAI PRECISION INDUSTRY CO., LTD., New Taipei (TW)

(21) Appl. No.: 14/256,146

(22) Filed: Apr. 18, 2014

(30) Foreign Application Priority Data
Apr. 3, 2013 (CN) 2013101551613

(51) Int. Cl. H05K 5/02; H05K 5/00

(52) U.S. Cl. CPC H05K 5/02; H05K 5/0017
USPC 361/679.01

(57) ABSTRACT

A flexible electronic device a bottom cover, an upper cover, and a positioning mechanism. The upper cover cooperates with the bottom cover to form a close space for receiving the positioning mechanism. The positioning mechanism bends with the flexible electronic device to form an angle by an external force. When the external force disappeares, the positioning mechanism keeps the flexible electronic device bent at the current angle.

### FIELD

The present disclosure relates to flexible electronic devices.

### BACKGROUND

Flexible electronic devices in a straightened state as shown in FIG. 6, such as mobiles and tablet computers, includes a bottom cover 10, an upper cover 20, a display panel 4. The bottom cover 10 cooperates with the upper cover 20 and the display panel to form a closed space. The bottom cover 10 and the upper cover 20 are all made of elastics material, and can be bent to form an angle by external force. When the external force disappears, the flexible electronic device automatically returns to the straightened state.

### BRIEF DESCRIPTION OF THE FIGURE

The components of the drawings are not necessarily drawn to scale, the emphasis instead being placed upon clearly illustrating the principles of the embodiment of a flexible electronic device. Moreover, in the drawings, like reference numerals designate corresponding parts throughout several views.

FIG. 1 is an isometric view of a flexible electronic device, according to an embodiment.

FIG. 2 is a partially disassembled isometric view of the flexible electronic device of FIG. 1; the electronic device includes a position portion.

FIG. 3 is a partially disassembled isometric view of the positioning portion of FIG. 2.

FIG. 4 is an isometric view of the flexible electronic device of FIG. 1 being bent.

FIG. 5 is isometric view of the positioning portion of FIG. 2 being bent.

FIG. 6 is isometric view of a flexible electronic device in a related art.

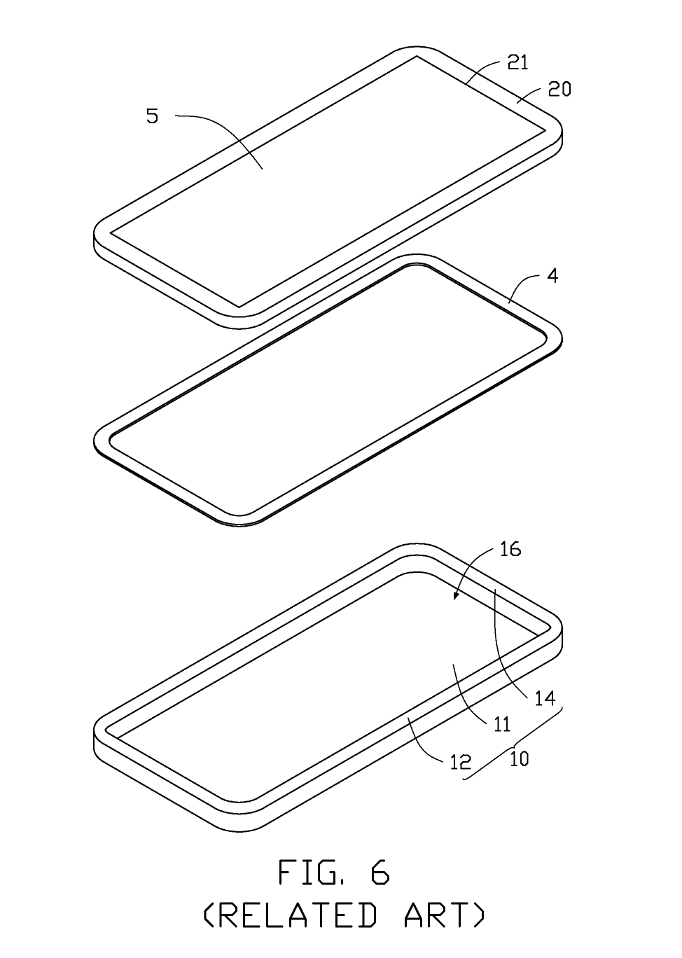

### DETAILED DESCRIPTION

Embodiments of the present disclosure will be described in detail with reference to the drawings.

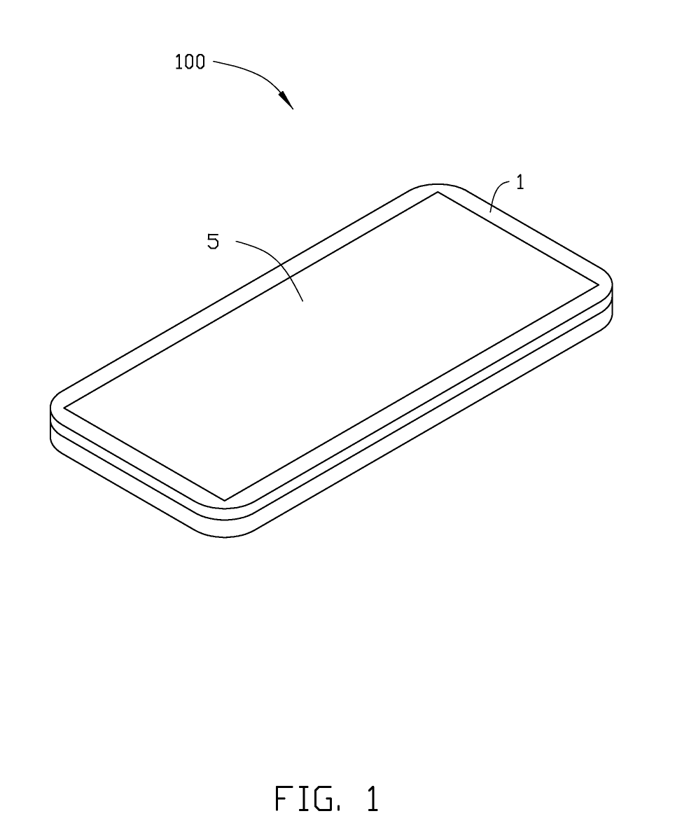

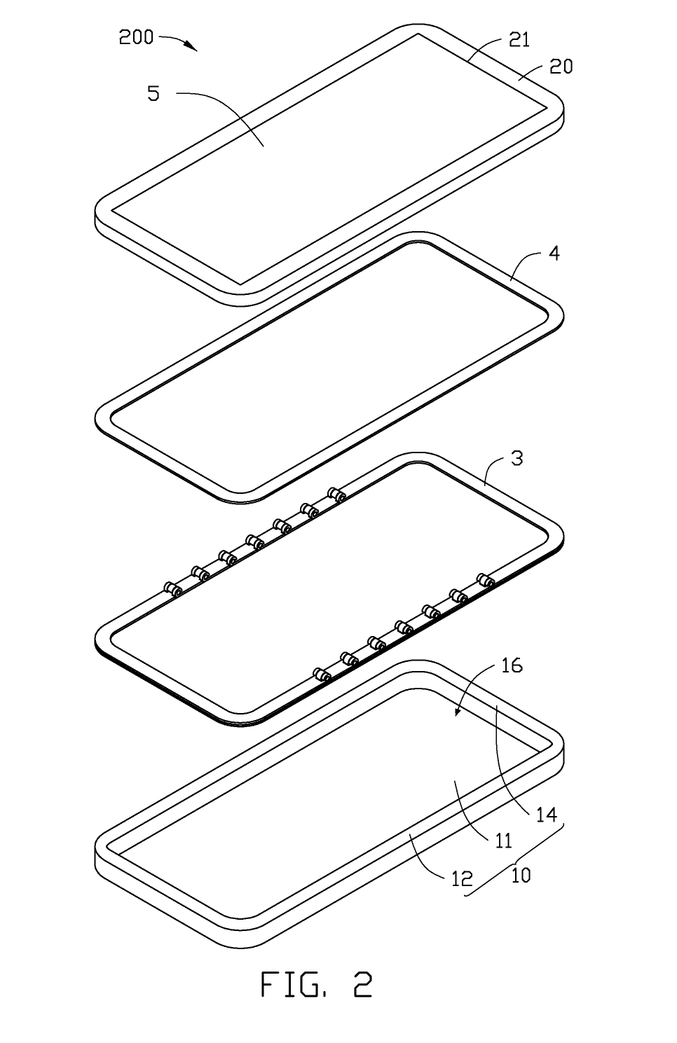

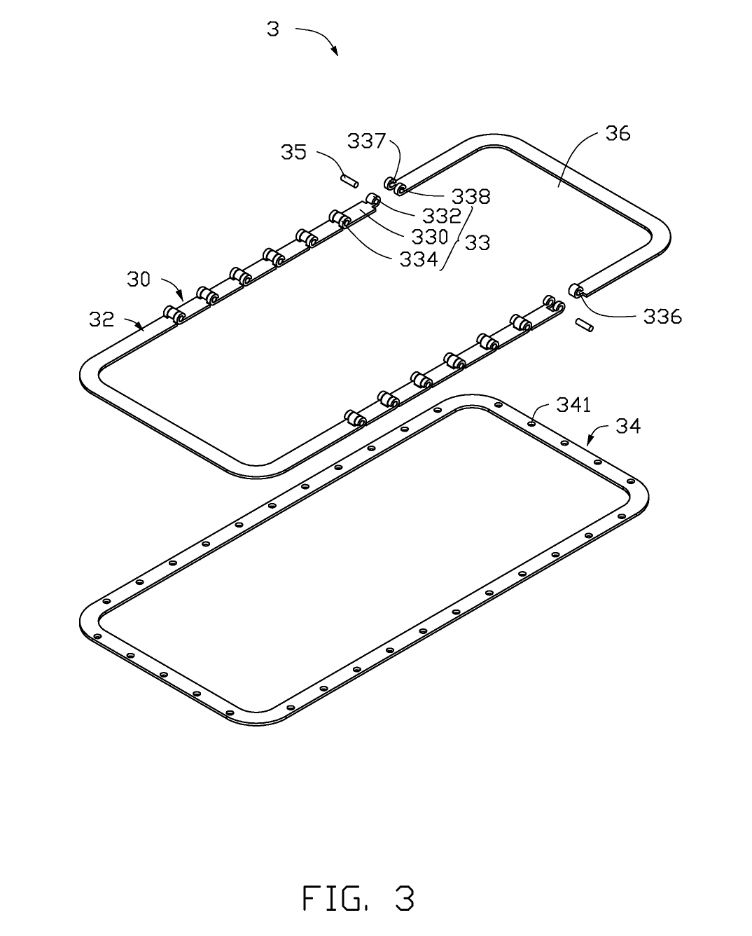

FIGS. 1-3 illustrate a flexible electronic device 100 of the embodiment. The flexible electronic device 100 can be bent by external force, and is capable of remaining bent when the external force disappears. In one embodiment, the flexible electronic device 100 is a mobile phone or a tablet computer, for example.

The flexible electronic device 100 includes a main body 1, a positioning mechanism 3, a base 4, and a cooperation portion 5.

The main body 1 includes a bottom cover 10 and an upper cover 20. The bottom cover 10 cooperates with the upper cover 20 to form a closed space (not labeled) for receiving other electronic components (not shown). In one embodiment, the main body 1 can be made of shape memory polymer. In other embodiments, the main body 1 can be made of other types of shape memory material.

The bottom cover 10 can be substantially rectangular. The bottom cover 10 includes a bottom plate 11, two first sidewalls 12, and two second sidewalls 14. The first sidewalls 12 and the second sidewalls 14 vertically extend from the four edges of the bottom plate 11, and cooperate with each other to form a first rectangular opening 16. The first sidewalls 12 are parallel with each other along a length direction. The second sidewalls 14 are parallel with each other along a width direction.

The upper cover 20 defines a receiving space 21 facing the opening 16.

The positioning mechanism 3 arranged on the first sidewall 12 and the second sidewall 14, and is sandwiched between the base 4 and the bottom cover 10. The positioning mechanism 3 includes a plurality pairs of first positioning members 30, two second positioning member 32, and a retainer member 34. The two second positioning members 32 are opposite to each other, and are connected with each other through the first positioning members 30 to form a second rectangular opening 36 facing the first opening 16. In one embodiment, the first positioning member 30 and the second positioning member are made of shape memory material. In one embodiment, the positioning mechanism 3 includes seven pairs of the first positioning member 30.

The first positioning members 30 in the same pair are arranged on the opposite first sidewalls 12 respectively. The first positioning members 30 on the same first sidewall 12 are serially interconnected with each other. The first positioning member 30 includes a rotating portion 33 and a pivot 35. The rotating portion 33 includes a connection portion 330, a first arm 332, and two second arms 334. The connection portion 330 is a substantially plate shaped. The first arm 332 and the second arms 334 are vertically extended from opposite ends of the connection portion 330 along a same direction, and bent in two opposite directions. The second arms 334 are spaced apart by a distance from each other to form a receiving portion 337 for receiving the first arm 332 of the adjacent first positioning member 30. The first arm 332 and the second arms 334 are substantially C-shaped. The first arm 332 defines a first through hole 336, and the second arm 334 defines a second through hole 338. The pivot 35 inserts through the first through hole 336 and the second through hole 338 while the receiving portion 337 formed by the two second arms 334 receives the first arm 332 of the adjacent first positioning member 30.

The second positioning member 32 is similar to the first positioning member 30, but the connection portion 330 of the second positioning member 32 is substantially U-shaped.

The retainer member 34 is substantially rectangular. The retainer member 34 is mounted on the first sidewalls 12 and the second sidewalls 34, and is covered by the first positioning member 30 and the second positioning member 34. The retainer member 34 defines a plurality of grooves 341 at the edge of the retainer 34 for decreasing the height of the retainer 34.

The base 4 is a substantially hollow rectangular member. The base 4 arranged on the bottom cover 20 touches the first sidewalls 12 and the second sidewalls 14 synchronously. The base 4 defines a plurality of grooves (not shown) facing the positioning mechanism 3 for receiving the second positioning member 32. In one embodiment, the base 4 is made of shape memory alloy. In other embodiments, the base 4 is made of other types of shape memory material.

The cooperation portion 5 is substantially rectangular, and is received in the receiving space 21. The cooperation portion 5 is made of shape memory material. In one embodiment, the cooperation portion 5 is a flexible display panel.

In other embodiment, the cooperation portion 5 can be a flexible crystal display panel, for example.

In assembly, the base 4 is adhered to the main body 1. The cooperation portion 5 is received in the receiving space 21, and substantially coplanar with the upper cover 20. The first arm 332 of the first positioning member 30 is inserted into the second arm 334 of the adjacent first positioning member 30 or the adjacent second positioning member 32, and the first through hole 336 of the first arm 332 is coaxial to the second through holes 338 of the second arm 334 where the first arm 332 is inserted. The pivot 35 is inserted into the first through hole 336 and the second through holes 338 which are coaxial with each other.

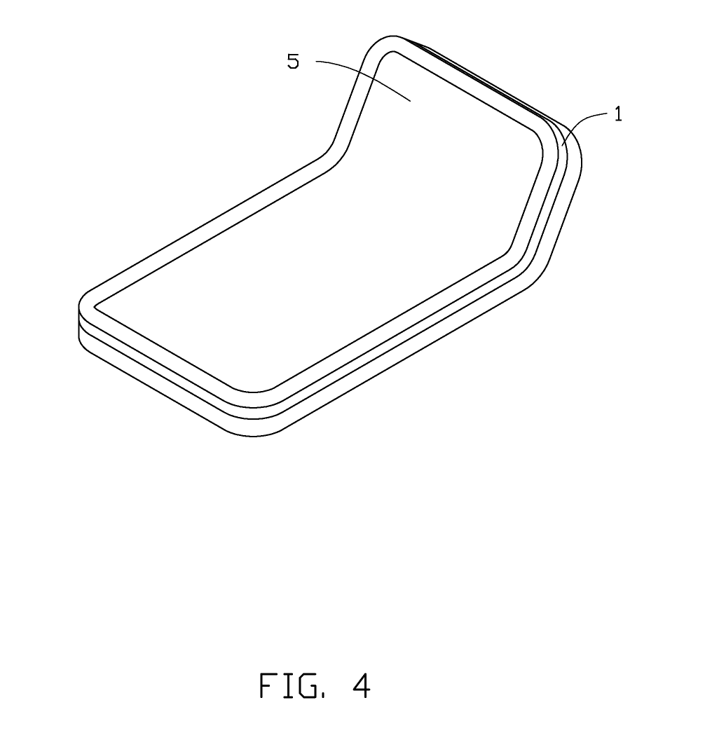

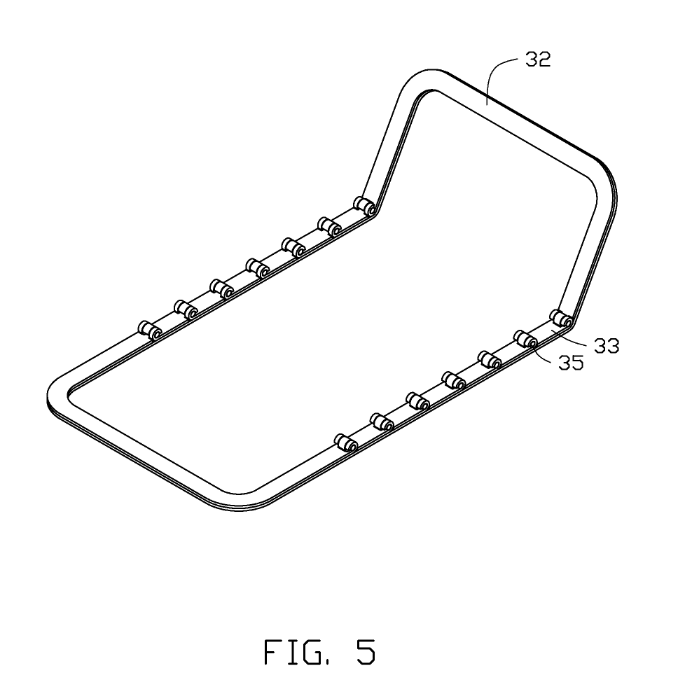

FIGS. 4-5 illustrate that the flexible electronic device 100 and the positioning mechanism 3 are bent simultaneously by an external force. When one pair of the first positioning members 30 is rotated about the axis of the corresponding pivot 35 in an anti-clockwise direction simultaneously. When the external force is removed, the bent angle of the flexible electronic device 100 remains based on a friction force between the rotated first positioning member 30 and the first positioning member 30 connected with the rotated pivot 35.

When one of the second positioning members 32 is rotated about the axis of the corresponding pivot 35 of the first positioning member 30 which is connected with the rotated second positioning member 32 in an anti-clockwise direction. When the external force is removed, the bent angle of the flexible electronic device 100 remains based on a friction force between the rotated second positioning member 32 and the adjacent first positioning member 30.

For straightening the bent flexible electronic device 100, the rotated pair of the first positioning member 30 or the rotated second positioning member 32 rotates about the axis of the pivot 35 along a clockwise direction opposite by the external force. When the external force is removed after the positioning mechanism 3 is straightened, the retainer member 34 supports the first positioning member 30 and the second positioning member 32 for keeping the positioning mechanism 3 being straightened.

As described, when the external force for bending the flexible electronic device 100 is removed, the flexible electronic device 100 remains bent by the positioning mechanism 3. Therefore, the flexible electronic device 100 can be bent to different angle.

While various exemplary and preferred embodiments have been described, the disclosure is not limited thereto. On the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A flexible electronic device, comprising:
a bottom cover;
an upper cover cooperated with the bottom cover to form a close space; and
a positioning mechanism mounted on the bottom cover and covered by the upper cover;
wherein the flexible electronic device is capable of bending to form an angle by an external force; the positioning mechanism retains the flexible electronic device at the current angle when the external force is removed.

2. The flexible electronic device of claim 1, wherein the bottom cover comprises two first sidewalls parallel with each other, the positioning mechanism comprises a plurality pairs of first positioning members; the first positioning members in the same pair are arranged on the opposite first sidewalls respectively; the first positioning member comprises a pivot; the first positioning members on the same first sidewall are serially rotataly interconnected with each other through the corresponding pivot; when the flexible electronic device is bent by one of the pair of the first positioning member rotated about an axis of the corresponding pivot in a first direction by the external force simultaneously, the rotated first positioning member remains in the current position keeping the flexible electronic device bent without the external force.

3. The flexible electronic device of claim 2, wherein the first positioning member further comprises a connection portion, a first arm, and two second arms; the first arm and the second arms are vertically extended from opposite ends of the connection portion and bent in opposite directions; the second arm are spaced from each other to form a receiving portion for receiving the first arm of the adjacent first positioning member; the first arm defines a first through hole, the second arm defines a second through hole; the pivot inserts the first through hole of the first positioning member and the second through hole of the adjacent first positioning member for connecting the adjacent first positioning member together.

4. The flexible electronic device of claim 2, wherein the connection portion of the first arm is substantially rectangular.

5. The flexible electronic device of claim 2, wherein the bottom cover further comprises two second sidewalls parallel with each other; the second sidewall is perpendicularly to the first sidewall; the second sidewalls cooperate with the first sidewalls to form a first rectangular opening; the positioning mechanism further comprises two second positioning members parallel with each other; the second positioning members are connected with each other through the first positioning members to form a second rectangular opening faced to the first rectangular opening; the second positioning member rotataly connected with the adjacent first positioning member; when the flexible electronic device is bent by one of the second positioning member rotated about an axis of the corresponding pivot of the connected first positioning member in a first direction by the external force, the rotated second positioning member remains in the current position keeping the flexible electronic device bent without the external force.

6. The flexible electronic device of claim 5, wherein the second positioning member further comprises a connection portion, a first arm, and two second arms; the first arm and the second arms are vertically extended from opposite ends of the connection portion and bent in opposite directions; the second arms are spaced from each other to form a receiving portion for receiving the first arm of the adjacent first positioning member, and the first arm is received between the second arms of the adjacent first positioning member; the first arm defines a first through hole, the second arms define a second through hole; the second positioning member connects with the first positioning member through the pivot of the adjacent first positioning member.

7. The flexible electronic device of claim 6, wherein the connection portion of the second arm is substantially U-shaped.

8. The flexible electronic device of claim 5, wherein the positioning mechanism further comprises a retainer member; the retainer member is mounted on the first sidewalls and the second sidewalls and is covered by the first positioning member and the second positioning member; when the external force is removed after the positioning mechanism being straightened, the retainer member supports the first positioning member and the second positioning member keeping the positioning mechanism straightened.
